(19) United States
(12) Patent Application Publication
(10) Pub. No.: US 2018/0130971 A1
(43) Pub. Date: May 10, 2018

(54) ORGANIC EL DISPLAY DEVICE

(71) Applicant: Japan Display Inc., Tokyo (JP)

(72) Inventors: Genki ASOZU, Tokyo (JP); Emi HIGANO, Tokyo (JP)

(21) Appl. No.: 15/804,125

(22) Filed: Nov. 6, 2017

(30) Foreign Application Priority Data
Nov. 8, 2016 (JP) 2016-218067

(51) Int. Cl. H01L 51/52; H01L 27/32

(52) U.S. Cl. CPC H01L 51/5218; H01L 27/3262; H01L 51/5253; H01L 27/322

(57) ABSTRACT

The purpose of the present invention is to realize the organic EL display device that has a high quality images even the polarizing plate is eliminated. The structure of the invention is as follows. An organic EL display device comprising: a display area, an organic EL element, which an organic EL layer is formed between a lower electrode and an upper electrode, the organic EL layer emits a different color of light according to a pixel, wherein a color filter of a same color as a color of light emitted from the organic EL layer is formed at a nearer side to the screen of the organic EL layer.

### CLAIM OF PRIORITY

The present application claims priority from Japanese Patent Application JP 2016-218067 filed on Nov. 8, 2016, the content of which is hereby incorporated by reference into this application.

### BACKGROUND OF THE INVENTION

### (1) Field of the Invention

The present invention relates to the Organic EL display device having high contrast images by suppressing reflection of the external light.

### (2) Description of the Related Art

An organic EL display device and a liquid crystal display device can be flexibly bent by making those displays thin. The substrate of the flexible display device is made by thin glass or resin. An organic EL display device can be made more flexible than a liquid crystal display device because an organic EL display device doesn't need a backlight.

The organic EL display device can be classified into two types; one type is that the emitting layers in different pixels emit three colors of red light, green light and blue light to form color images; another type is the emitting layers in different pixels emit white light and color filters are used to form color images. The organic EL display device can be further classified into: the bottom emission type that light is emitted from a bottom surface of the substrate where the TFTs (Thin Film Transistors) are formed, and the top emission type that light is emitted from a top surface of the substrate where the TFTs (Thin Film Transistors) are formed.

Patent document 1 (Japanese patent laid open No. 2009-87908) and Patent document 2 (Japanese patent laid open No. 2006-147364) disclose a bottom emission type organic EL display device that uses the white light emitting layer; the color filters are formed between the light emitting layer and the substrate.

### SUMMARY OF THE INVENTION

In an organic EL display device, a reflection electrode is used for a light emitting layer at the opposite side to the screen surface. The reflection electrode, however, reflects the external light, consequently, images on the screen becomes hard to watch. To avoid this phenomenon, a polarizing plate is adhered on the screen to suppress the reflection.

The polarizing plate is, however, high priced and raise the cost of the organic EL display. In addition, the polarizing plate is as thick as 0.15 mm if the adhesive is included, which is disadvantageous for making a thin display device.

The purpose of the present invention is to suppress the reflection of the external light without using the polarizing plate in the organic EL display device. The present invention can realize the above purpose; concrete measures are as follows:

(1) An organic EL display device comprising: a display area, an organic EL element, which an organic EL layer is formed between a lower electrode and an upper electrode, the organic EL layer emits a different color of light according to a pixel, wherein a color filter of a same color as a color of light emitted from the organic EL layer is formed at a nearer side to the screen of the organic EL layer.

(2) An organic EL display device comprising: a display area, an organic EL element, which an organic EL layer is formed between a lower electrode and an upper electrode, the organic EL layer emits a different color of light according to a pixel, wherein a color filter of a same color as a color of light emitted from the organic EL layer is formed at an opposite side to the screen of the organic EL layer.

(3) An organic EL display device comprising: a display area, an organic EL element, which an organic EL layer is formed between a lower electrode and an upper electrode, the organic EL layer emits a different color of light according to a pixel, wherein a color filter of a same color as a color of light emitted from the organic EL layer is formed at an opposite side to the screen of the organic EL layer, wherein a drain electrode or source electrode of a thin film transistor extends on an inorganic insulating film through a through hole formed in the inorganic insulating film, the color filter exists between the organic EL layer and the drain electrode or the source electrode, the drain electrode or the source electrode works as a reflection electrode.

### BRIEF DESCRIPTION OF THE DRAWINGS

FIG. 1 is a plan view of the flexible display device;

FIG. 2 is cross sectional view along the line A-A of the FIG. 1 as a comparative example;

FIG. 3 is a cross sectional view that shows the function of the comparative example;

FIG. 4 is a cross sectional view of the display area of the comparative example;

FIG. 5 is a cross sectional view of the present invention;

FIG. 6 is a cross sectional view that shows the function of embodiment 1 of the present invention;

FIG. 7 is a cross sectional view of the display area of embodiment 1;

FIG. 8 is a cross sectional view that shows the function of embodiment 2 of the present invention;

FIG. 9 is a cross sectional view of the display area of embodiment 2; and

FIG. 10 is cross sectional view of the display area of embodiment 3 of the present invention.

### DETAILED DESCRIPTION OF THE PREFERRED EMBODIMENTS

The present invention is explained in detail by embodiments.

### First Embodiment

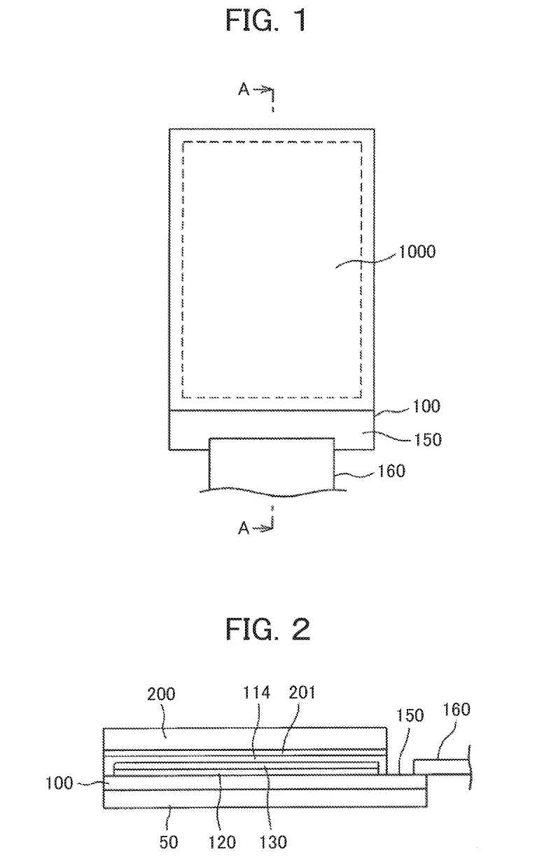

FIG. 1 is a plan view of the organic EL display device, which the present invention is applied, that has a flexible substrate. The display device of the present invention is an organic EL display device that can be flexibly bent. The organic EL display device doesn't need a back light, thus, it is advantageous for a flexible display device. The organic EL display device of FIG. 1 has the display area 1000 and the terminal area 150; the flexible wiring board 160 is connected to the terminal area 150.

FIG. 2 is a comparative example where a polarizing plate exists corresponding to the cross section along the line A-A of FIG. 1. In FIG. 2, the TFT layer 120, which includes TFTs, video signal lines, scanning lines and anode lines, is formed on the resin substrate 100. Among the resin substrates, the polyimide substrate has superior characteristics for a substrate of a flexible display device, thus, the following explanation is made as a premise that the substrate is a polyimide substrate; however, the present invention is applicable to a display device that has other resin substrates.

The array layer 130 that includes the organic EL layer is formed on the TFT layer 120. The protective layer 114 of silicon nitride (SiNx) is formed covering the array layer 130 to protect the organic EL layer formed in the array layer 130 from moisture. The polarizing plate 200 is adhered to the protective layer 114 by the adhesive 201. The organic EL display device of FIG. 2 is a top emission type. The top emission type has a reflection electrode for the organic EL layer at a side opposite to the screen surface. The reflection electrode, however, reflects the external light that makes images of the screen hard to watch. To avoid this phenomenon, a polarizing plate is adhered on the screen to suppress the reflection.

An area where the TFT layer 120 or array layer 130 are not formed is a terminal area 150. Lead lines extend from the TFT layer 120 into the terminal area to connect with terminals. The flexible wiring substrate 160 connects to the terminals to supply signals and power to the organic EL display device. The flexible wiring substrate 160 is connected to the terminals by e.g. thermo-compression bonding.

In FIG. 2, thickness of the polyimide substrate is approximately 10-20 μm, which may be inconvenient for handling the display device or the mechanical strength of the display device may not be enough. To countermeasure this problem, a support plate 50 formed by e.g. PET (polyethylene terephthalate) or acrylic may be adhered to the organic EL display device. A thickness of the support plate 50 is often 0.1 mm or more.

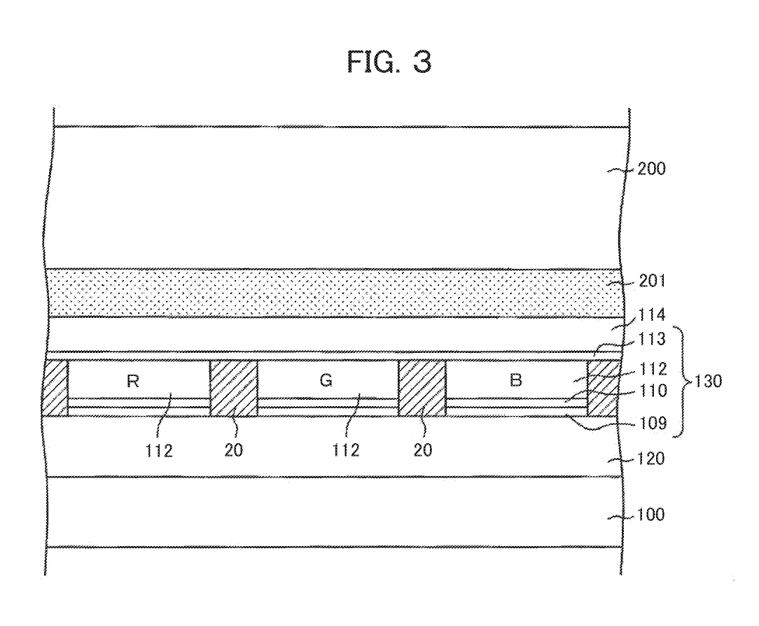

FIG. 3 is a cross sectional view that shows functions of the structure of FIG. 2. In FIG. 3, the TFT layer 120, which includes TFTs and wirings, is formed on the polyimide substrate 100; the array layer 130, which includes the organic EL layer, is formed on the TFT layer 120. The array layer 130 includes the organic EL layer 112, the lower electrode 110, the upper electrode 113 and the reflection electrode 109. In each of the pixels, the organic EL layer 112 of either one of red light emitting layer R, green light emitting layer G or blue light emitting layer B is formed. The black matrix 20 is formed between each of the organic EL layers 112.

The lower electrode 110 is formed by a transparent conductive film under the organic EL layer 112; the upper electrode 113 is formed by a transparent conductive film on the organic EL layer 112. The reflection electrode 109 is formed under the lower electrode 110 to reflect the light to the screen. The lower electrode 109 is separately formed in each of the pixels, and the upper electrode 113 is formed in common to the plural pixels.

In FIG. 3, the protective layer 114 is formed on the upper electrode 113 to protect the organic EL layer 112 from moisture. The polarizing plate 200 is adhered to the protective film 114 by adhesive 201.

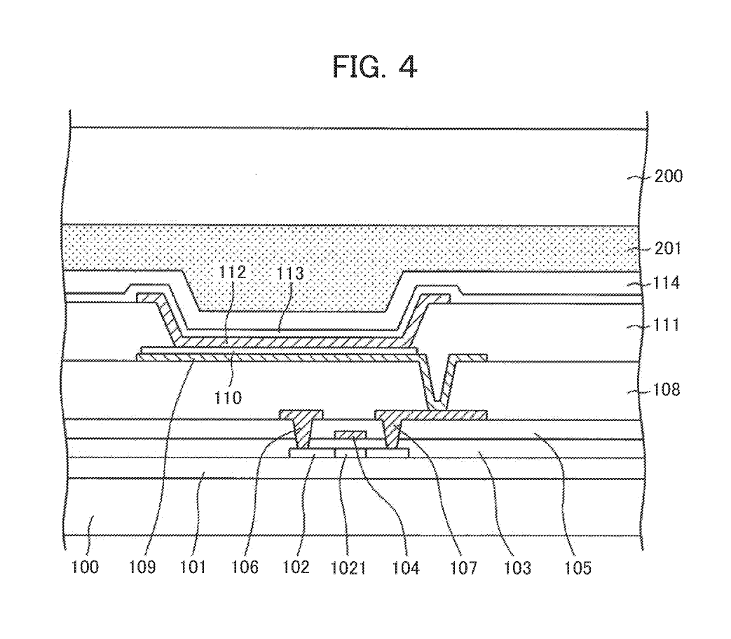

FIG. 4 is a detailed cross sectional view of the display area of the organic EL display device of FIGS. 2 and 3. In FIG. 4, the flexible substrate 100 is formed by polyimide at thickness of 10-20 μm. By the way, the flexible substrate is not necessarily made only by polyimide; it can be made by other resin or glass. The undercoat 101 is formed on the flexible substrate 100. The purpose of the undercoat 101 is mainly to stop moisture from the polyimide. The undercoat 101 is made by a laminated film of silicon oxide (SiOx) and silicon nitride (SiNx). The undercoat 101 can be made by e.g. a laminated film of, in order from the substrate, the SiOx layer of a thickness of 50 nm, the SiNx layer of a thickness of 50 nm, and the SiOx layer of a thickness of 200 nm.

The semiconductor layer 102 is formed on the undercoat 101. The semiconductor layer 102 is formed as that: the amorphous silicon a-Si layer is formed by CVD, then the amorphous silicon a-Si layer is transformed to the poly-silicon layer by irradiating excimer laser on the amorphous silicon a-Si layer.

The gate insulating film 103 of SiOx is formed on the semiconductor layer 102 by CVD using TEOS (Tetraethyl orthosilicate) as material. The gate electrode 104 is formed on the gate insulating film 103. After that, ion implantation is applied to give conductance to the semiconductor layer 102 except the area covered by the gate electrode 104. The channel 1021 is formed at the area corresponding to the gate electrode 104.

The interlayer insulating film 105 is formed covering the gate electrode 104 by SiNx formed by CVD. After that, through holes are formed through the interlayer insulating film 105 and the gate insulating film 103; then, the drain electrode 106 and the source electrode 107 are formed in the through holes. In FIG. 4, the organic passivation film 108 is formed covering the drain electrode 106, the source electrode 107 and the interlayer insulating film 105. The organic passivation film 108 has also a role as a flattening layer, thus, the thickness is as thick as 2-3 μm. The organic passivation film 108 is formed by e.g. acrylic.

The reflection electrode 109 is formed on the organic passivation film 108; the lower electrode 110 is formed by the transparent conductive film of e.g. ITO (Indium Tin Oxide) on the reflection electrode 109. The reflection electrode 109 is formed by e.g. Al, which has high reflectivity. The reflection electrode 109 connects with the source electrode 107 of the TFT through the through hole formed in the organic passivation film 108.

The bank 111 is formed covering the periphery of the lower electrode 110. The purpose of the bank 111 is to avoid a disconnection of the organic EL layer 112, which is formed subsequently, at the edge of the lower electrode 110. The process for the bank 111 is as follows: transparent resin of e.g. acrylic is coated on all over the display area and then, holes for the light emitting layers are formed in the acrylic layer at the areas corresponding to the lower electrodes 110. By the way, the bank 111 can be made as a black matrix by mixing black pigments in the resin.

In FIG. 4, the organic EL layer 112 is formed on the lower electrode 110. The organic EL layer 112 is formed by plural layers of e.g. the hole injection layer, the hole transport layer, the light emitting layer, the electron transport layer and the electron injection layer. The upper electrode 113 is formed as a cathode. The upper electrode 113 can be made by a transparent conductive film as IZO (Indium Zinc Oxide), ITO, etc. The upper electrode 113 can also be made by a thin metal as silver.

The protective layer 114 is formed on the upper electrode 113 by SiNx formed by CVD to prevent an intrusion of moisture to the organic EL layer 112 through the upper electrode 113. Since the organic EL layer 112 is weak to heat, the lower temperature CVD, at a temperature of about 100 centigrade, is adopted.

The top emission type organic EL layer has a reflection electrode 109, which reflects the external light; thus, contrast of the images are decreased. To prevent this phenomenon, the polarizing plate 200 is set on the screen to prevent the reflection of the external light. The polarizing plate 200 has an adhesive 201 at one side to adhere by pressing to the protective film 114 of the organic EL display device. A thickness of the adhesive 201 is e.g. 30 μm, and a thickness of the polarizing plate 200 is e.g. 120 μm

Since the polarizing plate is high priced, it raises a cost of the organic EL display device. In addition, the polarizing plate 200 is as thick as 0.15 mm (including the adhesive 201), thus, it is disadvantageous for realizing a thin display device. The purpose of the present invention is to eliminate the polarizing plate 200 from the organic EL display device without deteriorating the display quality

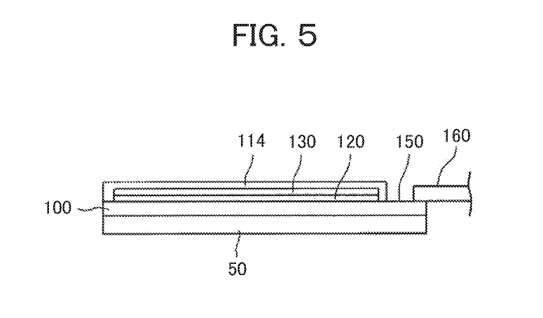

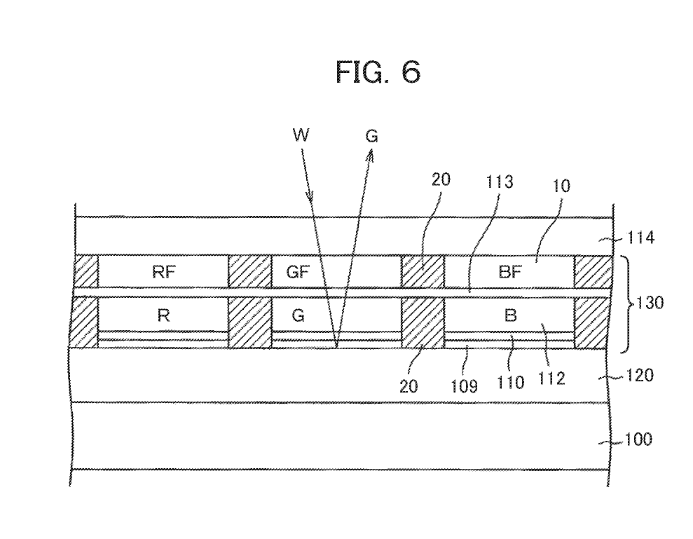

FIG. 5 is cross sectional view of the organic EL display device according to the present invention along the line A-A of FIG. 1. The structure of FIG. 5 is the same as FIG. 2 except there is no polarizing plate in FIG. 5. The structure of the array layer 120 of FIG. 6 is, however, is different from the structure of the array layer 120 of FIG. 2. The organic EL display device of FIG. 5 is thinner than that of FIG. 2 since FIG. 5 doesn't have a polarizing plate 200.

FIG. 6 is a cross sectional view that shows function of the first embodiment. In FIG. 6, TFT layer 120, which includes TFTs and wirings is formed on the polyimide substrate 100; the array layer 130, which includes the organic EL layer, is formed on the TFT layer 120. The array layer of the present embodiment includes the organic EL layer 112, the lower electrode 110, the upper electrode 113, the reflection electrode 109 and, further the color filter 110. In FIG. 6, RF is a red color filter, GF is a green color filter and BF is a blue color filter.

The lower electrode 110 is formed by a transparent conductive film under the organic EL layer; the upper electrode 113 is formed by a transparent conductive film on the organic EL layer. The reflection electrode 109 is formed under the lower electrode 110 to reflect the light to the screen. The lower electrode is separately formed in each of the pixels, and the upper electrode is formed in common to the plural pixels.

The feature of FIG. 6 is to set the color filter of the same color as the light emitted from the organic EL layer on the upper electrode 113. As shown in FIG. 6, the external light W, which is white color, goes through the organic EL layer 112, and goes through e.g. the green color filter GF, then, reflects at the reflection electrode 109. After that the light goes through the organic EL layer 112 and the green color filter GF again, then, is conceived by eyes of the human beings.

The red color light and the blue color light of the external light W are absorbed by the green color filter GF, the intensity of the external light becomes 1/3. In addition, the reflected external light penetrates the color filter 10 and the organic EL layer 112 twice, consequently, attenuation by those layers occur. Therefore, the reflection of the external light W can be substantially suppressed by using both the color filter 10 and the organic EL layer 112 even the polarizing plate 200 for suppressing the reflection of the external light is not used.

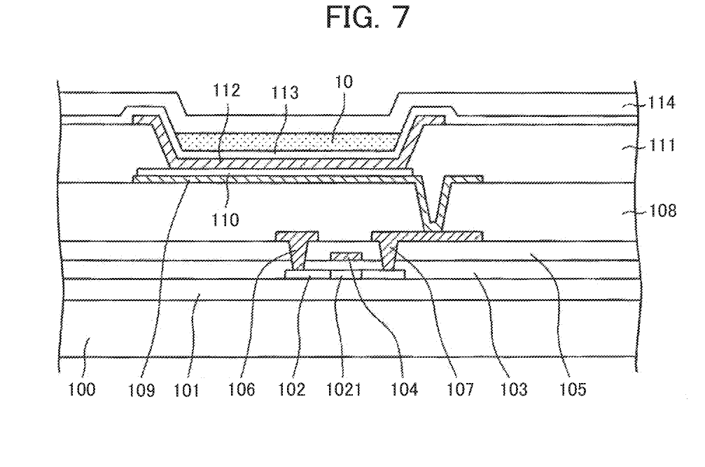

FIG. 7 is a cross sectional view of the pixel. FIG. 7 differs from FIG. 4 in that the color filter is formed on the upper electrode that is formed on the organic El layer; the color filter 10 is covered by the protective layer 114. There is no polarizing plate on the protective layer 114 in FIG. 7.

Different color filters must be formed in different pixels. When dry process like vacuum evaporation is applied to form the color filters 10, three evaporations are to be made using different masks. When wet process is applied to form the color filters 10, three times of lithography are applied to form three color filters.

On the other hand, the structure of FIG. 7 can be formed by inkjet. The inkjet is superior in productivity compared to other processes. In addition, the color filter 10 can be made lens shaped by controlling the viscosity, drying speed, etc. of the ink in the inkjet process. The lens shaped color filter can control the angular distribution of the emitting light.

By the way, the color filter in the present invention can be made on the counter substrate; and then, the counter substrate is attached to the substrate that the array layer 120 is formed.

The color filter 10 is formed directly on the upper electrode 113 in FIG. 7. In this structure, the pigments of the color filter may ooze out and influence the organic EL layer 112. To avoid this phenomenon, an overcoat made of e.g. acrylic can be formed between the upper electrode 113 and the color filter 10. The overcoat can be formed in common to plural pixels.

### Second Embodiment

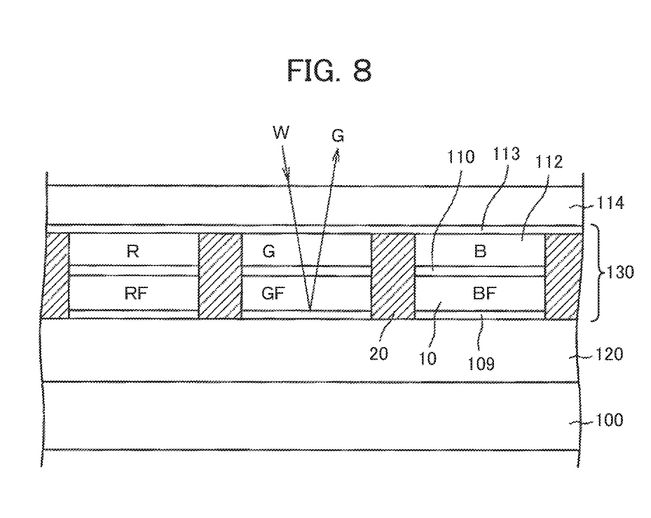

FIG. 8 is a cross sectional view that shows the function of the second embodiment. In FIG. 8, TFT layer 120, which includes TFTs and wirings, is formed on the polyimide substrate 100; the array layer 130, which includes the organic EL layer, is formed on the TFT layer 120. The array layer 130 includes the organic EL layer 112, the lower electrode 110, the upper electrode 113, the reflection electrode 109 and further, a color filter 10

The feature of the second embodiment is, at the outset, to form the reflection electrode 109, and the color filter 109 is formed on it. After that the lower electrode 110 is formed on the color filter 10; the organic EL layer 112 is formed on the lower electrode 110, and the upper electrode 113 covers the organic EL layer 112.

The feature of FIG. 8 is to set the color filter 10 of the same color as the light emitted from the organic EL layer 112 under the lower electrode 110. The reflection electrode 109 exists under the color filter 10. As shown in FIG. 8, the external light W, which is white color, goes through the organic EL layer 112, and goes through e.g. the green color filter GF, then reflects at the reflection electrode 109. After that the light goes through the green color filter GF and the organic EL layer 112 again, then, is conceived by eyes of the human beings.

The red color light and the blue color light of the external light W are absorbed by the green color filter GF, the intensity of the external light becomes 1/3. In addition, the reflected external light penetrates the color filter 10 and the organic EL layer 112 twice, consequently, attenuation by those layers occur. Therefore, the reflection of the external light can be substantially suppressed by using both the color filter 10 and the organic EL layer 112 even the polarizing plate 200 for suppressing the reflection of the external light is not used.

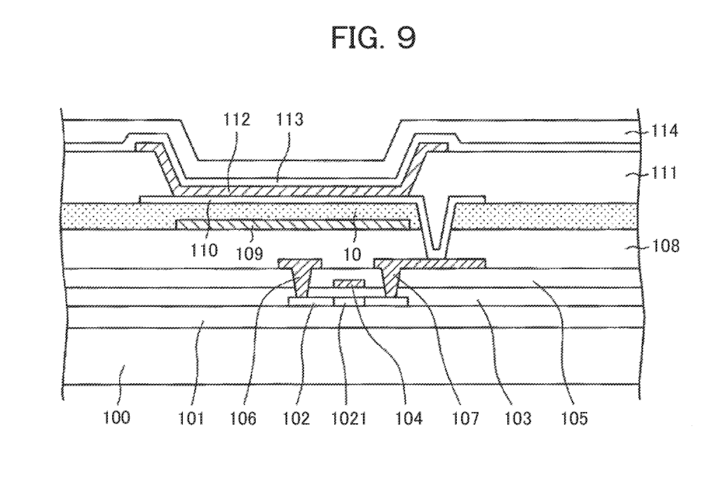

FIG. 9 is a cross sectional view of the pixel of the second embodiment. In FIG. 9, the reflection electrode 109 is formed on the organic passivation film 108. The color filter 10 is formed on the reflection electrode 109. The color filter is the same color as the light emitted from the organic EL layer 112, which is formed above the color filter 10.

In FIG. 9, the lower electrode 110 is formed on the color filter 10 by e.g. ITO. The lower electrode 110 connects with the source electrode 107 via the through hole formed in the color filter 10 and the organic passivation film 108; thus, video signals are supplied to the lower electrode 110.

The organic EL layer 112 is formed on the lower electrode 110; the upper electrode 113 is formed on the organic EL layer 112. The protective layer 114 is formed covering the upper electrode 113 to protect the organic EL layer 112. The polarizing plate does not exist on the protective layer. As explained in FIG. 8, reflection of the external light is suppressed to 1/3 or less, thus, perception of the image of the display is not significantly deteriorated.

In this embodiment too, different color filters must be formed in different pixels. When dry process like vacuum evaporation is applied to form the color filters 10, three evaporations are to be made using different masks. When wet process is applied to form the color filters 10, three times of lithography are applied to form three color filters. On the other hand, applying the inkjet method, different color filters can be made separately in each of the pixels.

### Third Embodiment

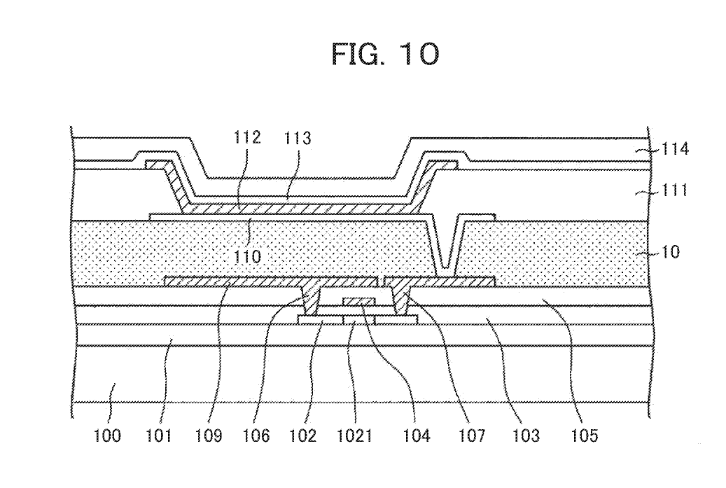

FIG. 10 is a cross sectional view of the third embodiment of the present invention. The present embodiment is the same as the second embodiment in that the color filter 10 is formed under the organic EL layer 112. Therefore, the function of the present embodiment is the same as the one that explained in FIG. 8. The feature of the present embodiment is that the present embodiment doesn't use the organic passivation film 108, but the color filter 10 is used, instead.

FIG. 10 is a cross sectional view of the display area of the third embodiment. In FIG. 10, the color filter 10 is formed on the drain electrode 106 or the source electrode 107, which are formed on the interlayer insulating film 105. The color filter 10 is e.g. the green color filter if the light emitted from the organic EL layer 112 is green.

The lower electrode 110 is formed on the color filter 10. The lower electrode 110 connects with the source electrode 107 of the TFT through the thorough hole formed in the color filter 10. The organic EL layer 112 is formed on the lower electrode 110; the upper electrode 113 is formed on the organic EL layer 112. The protective layer 114 is formed on the upper electrode 113. No polarizing plate exists on the protective layer 114.

The feature of FIG. 10 is to make the drain electrode in a large area in plane, thus, the drain electrode 106 can have a role of a reflection electrode 109; consequently, the manufacturing process for the reflection electrode 109 in embodiments 1 and 2 can be eliminated. By the way, the reflection electrodes of the first embodiment and the second embodiment are formed by the same material of the drain electrode (e.g. Al alloy). Thus, the reflection electrode of the present invention has the same reflective characteristics as the first embodiment and the second embodiment.

Although the drain electrode 106 is made wide in plane shape to form the reflection electrode in FIG. 10, the source electrode 107 can be made wide in plane shape to form the reflection electrode. Further, both of the drain electrode 106 and the source electrode 107 can be used as the reflection electrode.

In this embodiment, too, the reflection of the external light can be suppressed to 1/3 or less; therefore, the polarizing plate can be eliminated.

Although, in the above examples, only the protective layer 114 exists on the upper electrode 113, other protective layers can be added to improve a barrier effect against e.g. moisture. The structures of FIGS. 4, 7, 9 and 10 are only examples; the present invention is applicable to other structures. The substrate, which the TFT layer 120 is formed, is explained as a resin substrate; however, the present invention is applicable to the structure that the substrate is glass.

The above examples are for the top emission type organic EL display device; however, the function of the present invention is basically the same for the bottom emission type organic EL display device. In the bottom emission type organic EL display device, the laminating order of the organic EL layer, the lower electrode, the upper electrode, reflection electrode, and the color filter are changed.

What is claimed is:

1. An organic EL display device comprising:
a display area, and
an organic EL element, which an organic EL layer is formed between a lower electrode and an upper electrode,
wherein the organic EL layer emits a different color of light according to a pixel, and
wherein a color filter of a same color as a color of light emitted from the organic EL layer is formed at a nearer side to the screen of the organic EL layer.

2. The organic EL display device according to claim 1,
wherein the color filter is formed on the upper electrode.

3. The organic EL display device according to claim 1,
wherein an overcoat layer of resin is formed between the color filter and the upper electrode.

4. The organic EL display device according to claim 1,
wherein a reflection electrode is formed at the opposite side to the screen of the organic EL layer.

5. The organic EL display device according to claim 1,
wherein a reflection electrode is formed in contact with the lower electrode.

6. An organic EL display device comprising:
a display area, and
an organic EL element, which an organic EL layer is formed between a lower electrode and an upper electrode,
wherein the organic EL layer emits a different color of light according to a pixel, and
wherein a color filter of a same color as a color of light emitted from the organic EL layer is formed at an opposite side to the screen of the organic EL layer.

7. The organic EL display device according to claim 6,
wherein the color filter is formed under the lower electrode.

8. The organic EL display device according to claim 6,
wherein an overcoat layer of resin is formed between the color filter and the lower electrode.

9. The organic EL display device according to claim 6,
wherein a reflection electrode is formed in contact with the color filter.

10. The organic EL display device according to claim 6,
wherein a second inorganic protective film is formed on the organic protective film.

11. An organic EL display device comprising:
a display area, and
an organic EL element, which an organic EL layer is formed between a lower electrode and an upper electrode,
wherein the organic EL layer emits a different color of light according to a pixel,
wherein a color filter of a same color as a color of light emitted from the organic EL layer is formed at an opposite side to the screen of the organic EL layer,
wherein a drain electrode or source electrode of a thin film transistor extends on an inorganic insulating film through a through hole formed in the inorganic insulating film,
wherein the color filter exists between the organic EL layer and the drain electrode or the source electrode,
wherein the drain electrode or the source electrode works as a reflection electrode.

12. The organic EL display device according to claim 11,
wherein the color filter is formed in contact with the lower electrode.

13. The organic EL display device according to claim 11,
wherein an overcoat layer of resin is formed between the color filter and the lower electrode.

14. The organic EL display device according to claim 11,
wherein the lower electrode connects with the drain electrode or the source electrode through a through hole formed in the color filter.
